(19) United States
(12) Patent Application Publication
(10) Pub. No.: US 2025/0054806 A1
(43) Pub. Date: Feb. 13, 2025

(54) SEMICONDUCTOR MANUFACTURING APPARATUS AND METHOD OF MANUFACTURING SEMICONDUCTOR DEVICE

(71) Applicant: Mitsubishi Electric Corporation, Tokyo (JP)

(72) Inventors: Misato HISANO, Tokyo (JP); Noritsugu NOMURA, Tokyo (JP)

(73) Assignee: Mitsubishi Electric Corporation, Tokyo (JP)

(21) Appl. No.: 18/651,850

(22) Filed: May 1, 2024

(30) Foreign Application Priority Data
Aug. 9, 2023 (JP) 2023-129772

(51) Int. Cl. H01L 21/687; H01L 21/67; H01L 21/68; H01L 21/683; H01L 21/78

(52) U.S. Cl. CPC H01L 21/68757; H01L 21/67092; H01L 21/681; H01L 21/6836; H01L 21/78; H01L 2221/68322; H01L 2221/68386

(57) ABSTRACT

An object is to provide a technique that can prevent the fragments of the semiconductor wafer from scattering and adhering to the surfaces of the semiconductor devices when picking up the semiconductor devices that are cut into pieces from the semiconductor wafer. A semiconductor manufacturing apparatus includes a sheet holder that holds a sheet having a base material and an adhesive layer provided on a front surface of the base material to which the semiconductor wafer is adhered, and an adhesion strength reducer that is arranged to be able to act on the sheet held by the sheet holder and reduces adhesive strength in a predetermined area of the adhesive layer of the sheet. The predetermined area of the adhesive layer is an area to which fragments of the semiconductor wafer that do not function as the semiconductor devices are adhered.

### BACKGROUND OF THE INVENTION

### Field of the Invention

The present disclosure relates to a semiconductor manufacturing apparatus and a method of manufacturing a semiconductor device.

### Description of the Background Art

In a conventional semiconductor manufacturing apparatus, ultraviolet light is irradiated from the lower surface of semiconductor devices completely cut on a sheet that has a property of adhesive strength being reduced by ultraviolet light, and the semiconductor devices are peeled off from the sheet by the vertical movement of a push-up rod and a suction collet in each piece and picked up (see, for example, Japanese Patent Application Laid-Open No. 3-206643).

In the vicinity of the periphery of a semiconductor wafer, a plurality of small fragments of the semiconductor wafer are inevitably produced that do not form rectangular semiconductor devices. Those fragments of the semiconductor wafer cannot be used as a semiconductor device; therefore, the fragments of the semiconductor wafer are to be disposed of as waste along with the sheet after the semiconductor devices are picked up from the semiconductor wafer. The sizes the fragments of the semiconductor wafer vary depending on the size of the semiconductor device to be formed. Accordingly, with the miniaturization of semiconductor devices in recent years, the fragments of the semiconductor wafer are also becoming smaller in size.

In the conventional technology, when picking up semiconductor devices cut into pieces from the semiconductor wafer, the fragments of the semiconductor wafer adhered to a sheet scatter. As a result, the fragments of the semiconductor wafer adhere to surfaces of the semiconductor devices, causing defects in the semiconductor devices.

### SUMMARY

An object of the present disclosure is to provide a technique that can prevent the fragments of the semiconductor wafer from scattering and adhering to the surfaces of the semiconductor devices when picking up the semiconductor devices that are cut into pieces from the semiconductor wafer.

According to the present disclosure, a semiconductor manufacturing apparatus is a semiconductor manufacturing that manufactures a plurality of semiconductor devices obtained by cutting a semiconductor wafer into pieces. The semiconductor manufacturing apparatus includes a sheet holder and an adhesion strength reducer. The sheet holder holds a sheet having a base material and an adhesive layer provided on a first main surface of the base material to which the semiconductor wafer is adhered. The adhesion strength reducer is arranged to be able to act on the sheet held by the sheet holder and reduces adhesive strength in a predetermined area of the adhesive layer of the sheet. The predetermined area of the adhesive layer is an area to which fragments of the semiconductor wafer that do not function as the semiconductor devices are adhered.

Accordingly, the fragments of the semiconductor wafer can be removed before picking up the semiconductor devices that have been cut into pieces from the semiconductor wafer. Therefore, scattering of the fragments of the semiconductor wafer and adhering to the surfaces of the semiconductor devices can be suppressed when picking up the semiconductor devices that have been cut into pieces from the semiconductor wafer.

These and other objects, features, aspects and advantages of the present invention will become more apparent from the following detailed description of the present invention when taken in conjunction with the accompanying drawings.

### BRIEF DESCRIPTION OF THE DRAWINGS

FIG. 1 is a top view of a semiconductor wafer set in a semiconductor manufacturing apparatus according to Embodiment 1;

FIG. 2 is a side view illustrating a configuration related to a reduction in adhesive strength in the semiconductor manufacturing apparatus according to Embodiment 1;

FIG. 3 is a side view illustrating an example of a configuration related to removing fragments of the semiconductor wafer in the semiconductor manufacturing apparatus according to Embodiment 1;

FIG. 4 is a side view illustrating an other example of a configuration related to removing fragments of the semiconductor wafer in the semiconductor manufacturing apparatus according to Embodiment 1;

FIG. 5 is a side view illustrating an other example of a configuration related to removing fragments of the semiconductor wafer in the semiconductor manufacturing apparatus according to Embodiment 1;

FIG. 6 is a side view illustrating an other example of a configuration related to removing fragments of the semiconductor wafer in the semiconductor manufacturing apparatus according to Embodiment 1;

FIG. 7 is a flowchart of a semiconductor manufacturing method according to Embodiment; and

FIG. 8 is a side view illustrating a configuration related to reduction in adhesive strength in the semiconductor manufacturing apparatus according to Embodiment 2.

### DESCRIPTION OF THE PREFERRED EMBODIMENTS

### Embodiment 1

### <Configuration of Semiconductor Manufacturing Apparatus>

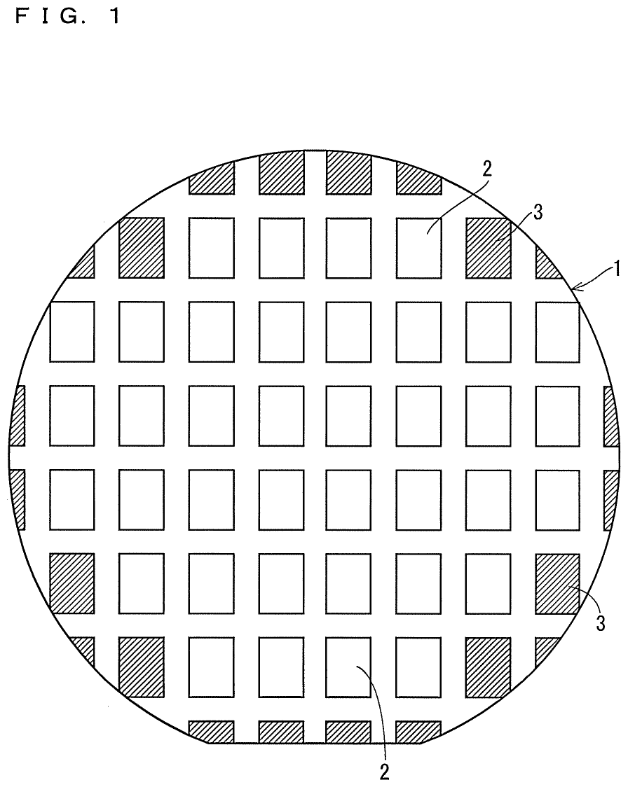

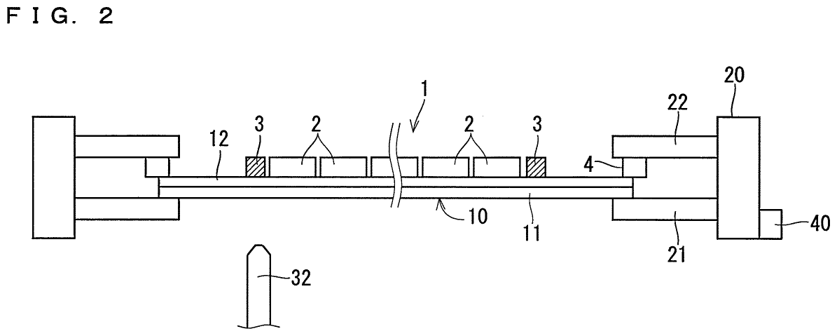

Embodiment 1 will be described with reference to the drawings. FIG. 1 is a top view of a semiconductor wafer 1 set in a semiconductor manufacturing apparatus according to Embodiment 1. FIG. 2 is a side view illustrating a configuration related to reduction in adhesive strength in the semiconductor manufacturing apparatus according to Embodiment 1.

First, the semiconductor wafer 1 set in the semiconductor manufacturing apparatus will be described. As illustrated in FIG. 1, the semiconductor wafer 1 is formed into a disk shape. A plurality of semiconductor devices 2 are formed on the semiconductor wafer 1 through steps such as coating, patterning, exposure, and etching. Then, the plurality of semiconductor devices 2 are processed into forms that can be taken out from the semiconductor wafer 1 by dicing, in which they are cut into pieces.

At this point, in the vicinity of the periphery of the semiconductor wafer 1, a plurality of small fragments 3 of the semiconductor wafer fragments 1 are inevitably produced that do not form rectangular semiconductor devices 2. The fragments 3 of the semiconductor wafer cannot be used because they do not function as the semiconductor devices 2. Therefore, the fragments 3 of the semiconductor wafer pieces are disposed of as waste.

Next, a semiconductor manufacturing apparatus according to Embodiment 1 will be described. As illustrated in FIG. 2, the semiconductor manufacturing apparatus includes a frame fixing unit 20 (corresponding to a sheet holder), a scanning energy irradiation device 32 (corresponding to an adhesive strength reducer), and a rotator 40.

The frame fixing unit 20 includes a frame supporting member 21 that is arranged on a base material 11 side of a sheet 10 and supports the sheet 10 from the base material 11 side, and a frame pressing member 22 that is arranged on an adhesive layer 12 side of the sheet 10 and holds down the sheet 10 from the adhesive layer 12 side. The sheet 10 is held by the frame supporting member 21 and the frame pressing member 22.

The sheet 10 includes the base material 11 and the adhesive layer 12 provided on the front surface (corresponding to the first main surface) of the base material 11 and to which the semiconductor wafer 1 is adhered. The sheet 10 is formed into a disk shape to fit the shape of the semiconductor wafer 1, and has a contour larger than the contour of the semiconductor wafer 1 in top view. On the adhesive layer 12 of the sheet 10, a plurality of semiconductor devices 2, that have been cut into pieces, of the semiconductor wafer 1 by dicing and the fragments 3 of the semiconductor wafer are adhered.

The frame fixing unit 20 fixes and supports the dicing frame 4 attached to the periphery of the semiconductor wafer 1. Specifically, the frame supporting member 21 supports the entire area or a portion of the periphery of the base material 11 of the sheet 10, and the frame pressing member 22 presses the entire area or a portion of the dicing frame 4 toward the frame supporting member 21 side, thereby fixing the sheet 10, to which the semiconductor wafer 1 is adhered, in a stretched manner without any slack.

The rotator 40 is provided inside or outside the frame fixing unit 20 to rotate the frame fixing unit 20 so that the vertical positional relationship between the frame supporting member 21 and the frame pressing member 22 of the frame fixing unit 20 is reversed. The rotator 40 is composed of, for example, a motor, gears, and the like.

An adhesive whose adhesive strength reduces with energy is adopted to the adhesive layer 12 of the sheet. Here, the energy for reducing the adhesive strength is any of light including ultraviolet (UV) light, heating, cooling, or radiation.

As illustrated in FIG. 2, the energy irradiation device 32 is arranged so as to be able to act on the sheet 10 held by the frame fixing unit 20. Specifically, the energy irradiation device 32 is arranged below the base material 11 of the sheet 10. The energy irradiation device 32 irradiates the sheet 10 with energy for reducing the adhesive strength while scanning.

The energy irradiation device 32 irradiates an area to which the fragments 3 of the semiconductor wafer presenting in the vicinity of the periphery of the semiconductor wafer 1 in the sheet 10 are adhered (that is, the adhesion layer 12) with energy for reducing the adhesive strength, thereby reducing the adhesive strength of the adhesive layer 12 of the sheet 10. Here, it is desirable that the energy irradiation area is approximately 1 mm×1 mm to 20 mm×20 mm depending on the size of the fragments 3 of the semiconductor wafer. Further, when heating is adopted as the energy for reducing the adhesive strength, it is desirable that the temperature of the sheet 10 is 60° C. to 200° C., and when it is cooling, the temperature of the sheet 10 is preferably −90° C. to −40° C. Note that the area on the adhesive layer 12 to which fragments 3 of the semiconductor wafer are adhered corresponds to a predetermined area where the adhesive strength is to be reduced.

Reducing the adhesion strength of the adhesive layer 12 of the sheet 10 to which the fragments 3 of the semiconductor wafer are adhered, enables to remove the fragments 3 of the semiconductor wafer before picking up the semiconductor devices 2 from the sheet 10. Therefore, scattering of the fragments 3 of the semiconductor wafer and adhering to the surfaces of the semiconductor devices 2 can be suppressed when picking up the semiconductor devices 2 that have been cut into pieces. Furthermore, the adhesion of the adhesive layer 12 to the semiconductor devices 2 is maintained when the fragments 3 of the semiconductor wafer are removed, peeling of the semiconductor devices 2 from the sheet 10 can be suppressed.

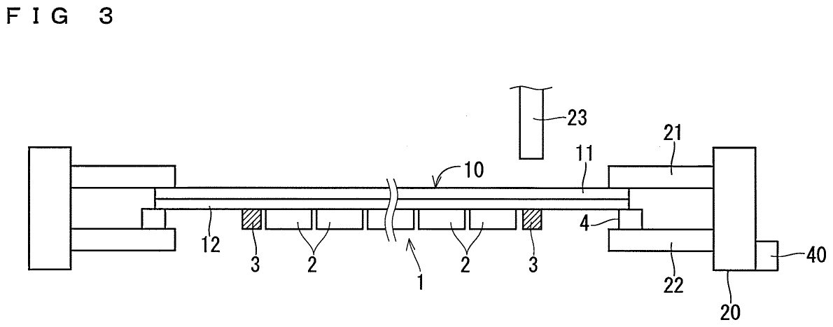

Next, a specific method for removing the fragments 3 of the semiconductor wafer, which is performed after reducing the adhesive strength of the adhesive layer 12 of the sheet 10, will be described referring to FIGS. 3 to 6. FIG. 3 is a side view illustrating an example of a configuration related to removing the fragments 3 of the semiconductor wafer in the semiconductor manufacturing apparatus according to Embodiment 1. Note that in FIGS. 3 to 6, illustration of the energy irradiation device 32 is omitted.

As illustrated in FIG. 3, the rotator 40 rotates the frame fixing unit 20 so that the vertical positional relationship between the frame supporting member 21 and the frame pressing member 22 of the frame fixing unit 20 is reversed with respect to the configuration illustrated in FIG. 2, and the adhesive layer 12 of the sheet 10 is held facing downward. The semiconductor manufacturing apparatus further includes a push-down unit 23, and the push-down unit 23 is arranged above the base material 11 of the sheet 10. Here, the adhesion of the adhesive layer 12 of the sheet 10 is maintained, so that the semiconductor devices 2 do not peel off from the sheet 10.

When removing the fragments 3 of the semiconductor wafer, the push-down unit 23 is arranged above the fragments 3 of the semiconductor wafer to be removed by moving either the push-down unit 23 or the sheet 10 in the horizontal direction.

Next, by lowering the push-down unit 23, the lower end of the push-down unit 23 is brought into contact with the base material 11 of the sheet 10, and the fragments 3 of the semiconductor wafer are pushed down through the sheet 10. The vertical motion of the push-down unit 23 can be executed by driving a motor or an air cylinder (not illustrated).

The fragments 3 of the semiconductor wafer peeled off from the sheet 10 can be removed downward by the push-down unit 23; therefore, the fragments 3 of the semiconductor wafer are suppressed from adhering to the surfaces of the semiconductor devices 2 to produce defects.

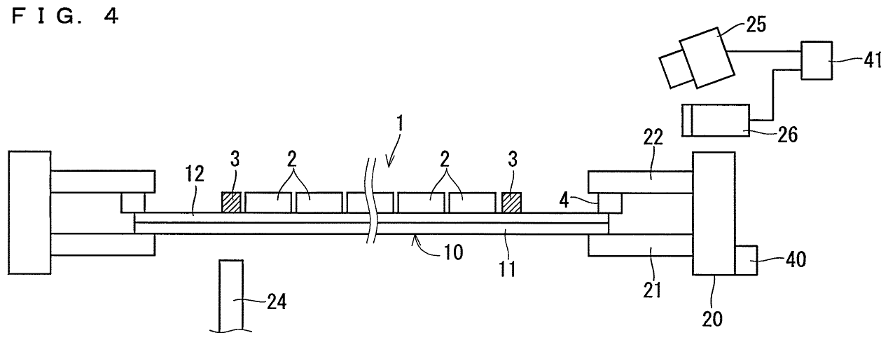

FIG. 4 is a side view illustrating an other example of a configuration related to removing the fragments 3 of the semiconductor wafer in the semiconductor manufacturing apparatus according to Embodiment 1.

As illustrated in FIG. 4, the semiconductor manufacturing apparatus further includes a push-up unit 24, a camera 25, an air gun 26, and a controller 41 in addition to the configuration illustrated in FIG. 2. Further, similar to the configuration in FIG. 2, the frame fixing unit 20 holds the sheet 10 so that the base material 11 of the sheet 10 faces downward.

The camera 25 is arranged above and to the side of the sheet 10 so as to monitor the entire front surface of the sheet 10, and identifies the fragments 3 of the semiconductor wafer. The air gun 26 is arranged above and to the side of the sheet 10, and ejects air toward the fragments 3 of the semiconductor wafer. The controller 41 controls the camera 25 and the air gun 26.

The push-up unit 24 is arranged below the base material 11 of the sheet 10. Here, the push-up unit 24 is arranged below the fragments 3 of the semiconductor wafer to be removed by moving either the push-up unit 24 or the sheet 10 in the horizontal direction.

Next, by raising the push-up unit 24, the upper end of the push-up unit 24 is brought into contact with the base material 11 of the sheet 10, and the fragments 3 of the semiconductor wafer are pushed up through the sheet 10. The vertical motion of the push-up unit 24 can be executed by driving a motor or an air cylinder (not illustrated).

When the fragments 3 of the semiconductor wafer are peeled off from the adhesive layer 12 of the sheet 10 by the push-up unit 24, scattering of the fragments 3 of the semiconductor wafer is highly likely to happen. Therefore, when the camera 25 identifies the fragments 3 of the semiconductor wafer peeled off from the adhesive layer 12 by the push-up unit 24, the controller 41 controls the air gun 26 to eject air to remove the fragments 3 of the semiconductor wafer from above the adhesive layer 12. Accordingly, the fragments 3 of the semiconductor wafer are suppressed from adhering to the surfaces of the semiconductor devices 2. Here, the camera 25 and the air gun 26 are not limited to one set, and two or more sets may be provided. In addition to dry air, the air ejected from the air gun 26 may be dry nitrogen.

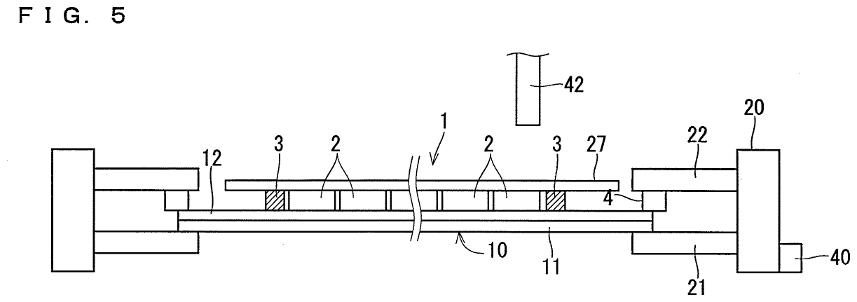

FIG. 5 is a side view illustrating an other example of a configuration related to removing the fragments 3 of the semiconductor wafer in the semiconductor manufacturing apparatus according to Embodiment 1.

As illustrated in FIG. 5, the semiconductor manufacturing apparatus further includes a tape attachment/detachment unit 42 in addition to the configuration illustrated in FIG. 2. The tape attachment/detachment unit 42 attaches a tape 27, having the lower adhesive strength than that of the adhesive layer 12 before the adhesive strength thereof is reduced yet and the higher adhesive strength than that of adhesive layer 12 after the adhesive strength thereof is reduced, to a surface opposite side of the surface in contact with the adhesive layer 12 in the semiconductor wafer 1, and then, peels the tape 27 off.

At this point, the adhesion of the adhesive layer 12 to the semiconductor devices 2 is maintained; therefore, the semiconductor devices 2 are not peeled off by the tape 27, and only the fragments 3 of the semiconductor wafer can be removed from the sheet 10. Therefore, scattering of the fragments 3 of the semiconductor wafer and adherence to the surfaces of the semiconductor devices 2 are suppressed when picking up the semiconductor devices 2 that have been cut into pieces.

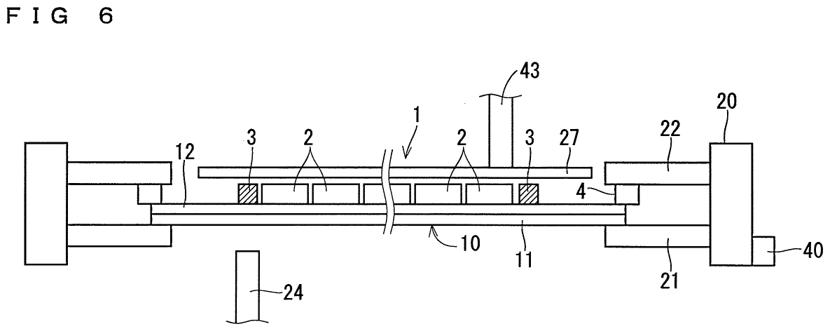

FIG. 6 is a side view illustrating an other example of a configuration related to removing the fragments 3 of the semiconductor wafer in the semiconductor manufacturing apparatus according to Embodiment 1.

As illustrated in FIG. 6, the semiconductor manufacturing apparatus further includes a tape holder 43 and the push-up unit 24 in addition to the configuration illustrated in FIG. 2. The tape holder 43 holds a tape 27, having the lower adhesive strength than that of the adhesive layer 12 before the adhesive strength thereof is reduced yet and the higher adhesive strength than that of adhesive layer 12 after the adhesive strength thereof is reduced, above the semiconductor wafer 1 so that the adhesive surface of the tape 27 faces the surface opposite side of the surface in contact with the adhesive layer 12 in the semiconductor wafer 1. The push-up unit 24 is arranged below the base material 11 of the sheet 10.

Next, by raising the push-up unit 24, the upper end of the push-up unit 24 is brought into contact with the base material 11 of the sheet 10, and the fragments 3 of the semiconductor wafer are pushed up through the sheet 10.

Note that when the push-up unit 24 has a function of irradiating energy for reducing the adhesive strength of the adhesive layer 12, the push-up unit 24 may irradiate the energy at this point as well. This enables to reduce the adhesion strength of the adhesion layer 12 of the sheet 10 earlier; therefore, swift removal of the fragments 3 of the semiconductor wafer can be performed in one step without energy irradiation in the previous step.

As the push-up unit 24 rises, the sheet 10 stretches, and the surface opposite side of the surface in contact with the adhesive layer 12 in the semiconductor wafer 1 adheres to the tape 27 arranged above. At this point, the adhesive strength of the tape 27 is higher than that of the adhesive layer 12 after the adhesive strength has been reduced; therefore, the fragments 3 of the semiconductor wafer are peeled off from the adhesive layer 12 of the sheet 10 and are adhered to the tape 27. The fragments 3 of the semiconductor wafer can be removed from the sheet 10 by adhesion of the fragments 3 to the tape 27; therefore, the fragments 3 of the semiconductor wafer do not adhere to the surfaces of the semiconductor devices 2.

Also, the adhesion of the adhesive layer 12 of the sheet 10 is maintained, so that the semiconductor devices 2 are not peeled off by the tape 27. Further, the tape 27 does not come into contact with the semiconductor devices 2, the adhesive surface of the tape 27 does not adhere to the surfaces of the semiconductor devices 2. Therefore, the semiconductor devices 2 in the necessary area are not peeled off from the adhesive layer 12 of the sheet 10. Afterward, scattering of the fragments 3 of the semiconductor wafer and adherence to the surfaces of the semiconductor devices 2 are suppressed when picking up the semiconductor devices 2 that have been cut into pieces, because the fragments 3 of the wafer have already been removed from the adhesive layer 12 of the sheet 10.

Note that after removing the fragments 3 of the semiconductor wafer, the semiconductor devices 2 are picked up from the sheet 10, and at that point, energy for reducing the adhesive strength may be irradiated onto the area of the sheet 10 where the semiconductor devices 2 are adhered. The energy irradiation reduces the adhesive strength of the adhesive layer 12 of the sheet 10, making picking up of the semiconductor devices 2 facilitated.

### <Manufacturing Method of Semiconductor Device>

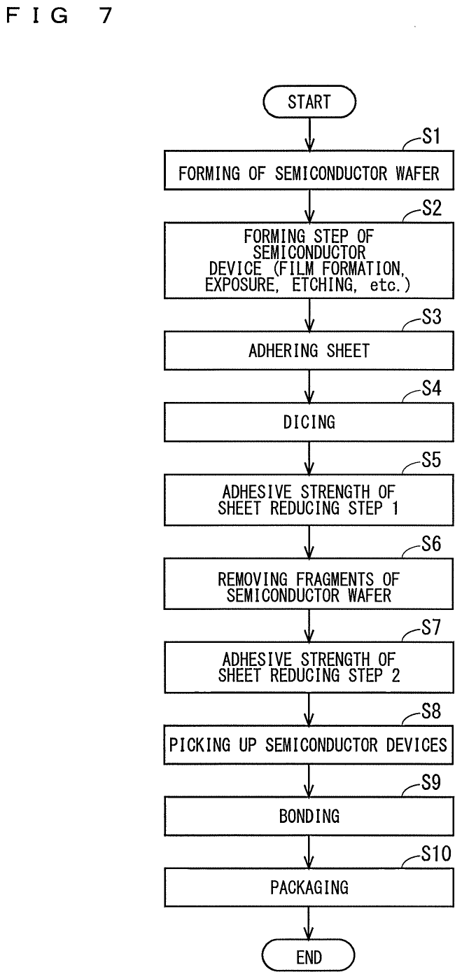

Next, a method of manufacturing the semiconductor device 2 will be described referring to the flowchart of FIG. 7. FIG. 7 is the flowchart of the method of manufacturing of the semiconductor device according to Embodiment 1.

As illustrated in FIG. 7, first in Step S1, the semiconductor wafer 1 is formed. Specifically, a disk-shaped semiconductor wafer 1 is obtained by slicing a single crystal ingot. Here, the semiconductor wafer 1 includes a silicon wafer or a compound semiconductor wafer such as silicon carbide, gallium arsenide, gallium phosphide, or gallium nitride.

In Step S2, a plurality of electric circuits that will become the semiconductor devices 2 are formed by performing well-known processes such as film formation, exposure, and etching.

In Step S3, the back surface of the semiconductor wafer 1 is adhered to the adhesive layer 12 of the sheet 10.

In Step S4, the semiconductor wafer 1 adhered to the sheet 10 is diced, thereby dividing the semiconductor wafer 1 into a plurality of semiconductor devices 2 and the fragments 3 of the semiconductor wafer that do not function as the semiconductor devices 2.

In Step S5, the adhesive strength of the area of the adhesive layer 12 of the sheet 10 to which the fragments 3 of the semiconductor wafer are adhered is reduced. Specifically, energy for reducing the adhesive strength of the adhesive layer 12 is irradiated onto an area to which the fragments 3 of the semiconductor wafer presenting in the vicinity of the periphery of the semiconductor wafer 1 in the sheet 10 are adhered, thereby reducing the adhesive strength of the adhesive layer 12 of the sheet 10. Here, the adhesion strength in all areas of the sheet 10 to which the fragments 3 of the semiconductor wafer are adhered is not necessarily reduced.

In Step S6, the fragments 3 of the semiconductor wafer whose adhesive strength of the adhesive layer 12 of the sheet 10 has been reduced are removed from the adhesive layer 12 of the sheet 10. Accordingly, scattering of the fragments 3 of the semiconductor wafer and adherence to the surfaces of the semiconductor devices 2 are suppressed when picking up the semiconductor devices 2 that have been cut into pieces, thereby improving the yield of the semiconductor device 2.

In Step S7, energy for reducing the adhesive strength of the adhesive layer 12 is irradiated yet again onto the area to which the plurality of semiconductor devices 2 are adhered in the adhesive layer 12, thereby reducing the adhesive strength of the adhesive layer 12 of the sheet 10. Furthermore, Step S7 is a step for making picking up of the semiconductor devices 2 from the adhesive layer 12 of the sheet 10 facilitated in the next step, Step S8, and when removal of the semiconductor devices 2 from the adhesive layer 12 of the sheet 10 is enabled to be executed without reducing the adhesion strength, Step S7 may be omitted.

In Step S8, the semiconductor devices 2 cut into pieces are picked up from the adhesive layer 12 of the sheet 10.

In Step S9, each picked up semiconductor device 2 is fixed to a conductive pattern, and the semiconductor device 2 is electrically connected to the conductive pattern via a thin metal wire or the like.

In Step S10, the semiconductor device 2 and the conductive pattern are sealed so as to be covered.

Here, between Steps S3 and S4, or between Steps S8 and S9, or both, the characteristics of a plurality of electric circuits formed on the surface of the semiconductor wafer 1 may be checked using a probe or the like. Then, sorting between good products and defective products, and not allowing semiconductor devices 2 with defective electric circuits to proceed to Step S9 may be adoptable.

### <Effect>

As described above, in Embodiment 1, the semiconductor manufacturing apparatus includes the sheet holder that holds the sheet 10 having the base material 11 and the adhesive layer 12 provided on the surface of the base material 11 and to which the semiconductor wafer 1 is adhered, and the adhesive strength reducer that is arranged to be able to act on the sheet 10 held by the sheet holder and reduces the adhesive strength in a predetermined area of the adhesive layer 12 of the sheet 10. The predetermined area on the adhesive layer 12 is an area to which the fragments 3 of the semiconductor wafer that do not function as the semiconductor devices 2 are adhered. Here, the adhesion strength reducer is the scanning type energy irradiation device 32 that irradiates the sheet 10 with energy for reducing the adhesion strength while scanning. Here, the energy is any of light including ultraviolet (UV) light, heating, cooling, or radiation. Also, the sheet holder is the frame fixing unit 20 that fixes and supports the dicing frame 4 attached to the periphery of the semiconductor wafer 1.

Accordingly, the fragments 3 of the semiconductor wafer can be removed before picking up the semiconductor devices 2 cut into pieces from the semiconductor wafer 1. Therefore, scattering of the fragments 3 of the semiconductor wafer and adhering to the surfaces of the semiconductor devices 2 can be suppressed when picking up the semiconductor devices 2 that have been cut into pieces from the semiconductor wafer 1.

Further, the frame fixing unit 20 holds the sheet 10 so that the adhesive layer 12 faces downward, and the semiconductor manufacturing apparatus further includes the push-down unit 23 that is brought into contact with the base material 11 and pushes down the fragments 3 of the semiconductor wafer through the sheet 10.

Therefore, the fragments 3 of the semiconductor wafer can be removed downward; therefore, the fragments 3 of the semiconductor wafer are suppressed from adhering to the surfaces of the semiconductor devices 2.

In addition, the semiconductor manufacturing apparatus further includes the rotator 40 that rotates the frame fixing unit 20; therefore, the step of removing the fragments 3 of the semiconductor wafer downward is made facilitated by turning over the sheet 10 on which the semiconductor wafer 1 is adhered.

Further, the sheet holder holds the sheet 10 so that the base material 11 faces downward. The semiconductor manufacturing apparatus further includes the push-up unit 24 that comes into contact with the base material 11 and pushes up the fragments 3 of the semiconductor wafer through the sheet 10, the camera 25 that identifies the fragments 3 of the semiconductor wafer, the air gun 26 that ejects air toward the fragments 3 of the semiconductor wafer, and the controller 41 that causes the air gun 26 to eject air when the camera 25 identifies the fragments 3 of the semiconductor wafer that have been peeled off from the adhesive layer 12 by the push-up unit 24 to remove the fragments 3 of the semiconductor wafer from the adhesive layer 12.

Therefore, the fragments 3 of the semiconductor wafer can be blown away toward the outer circumferential side of the sheet 10, thereby, suppressing the fragments 3 of the semiconductor wafer from adhering to the surfaces of the semiconductor devices 2.

Also, the semiconductor manufacturing apparatus further includes the tape attachment/detachment unit 42 that attaches a tape 27, having the lower adhesive strength than that of the adhesive layer 12 before the adhesive strength thereof is reduced yet and the higher adhesive strength than that of adhesive layer 12 after the adhesive strength thereof is reduced, to a surface opposite side of the surface in contact with the adhesive layer 12 in the semiconductor wafer 1, and then, peels the tape 27 off.

Therefore, the fragments 3 of the semiconductor wafer can be adhered to the tape 27 and removed; therefore, the fragments 3 of the semiconductor wafer are suppressed from adhering to the surfaces of the semiconductor devices 2.

The semiconductor manufacturing apparatus further includes the tape holder 43 that holds a tape 27, having the lower adhesive strength than that of the adhesive layer 12 before the adhesive strength thereof is reduced yet and the higher adhesive strength than that of adhesive layer 12 after the adhesive strength thereof is reduced, above the semiconductor wafer 1 so that the adhesive surface of the tape 27 faces the surface opposite side of the surface in contact with the adhesive layer 12 in the semiconductor wafer 1, and the push-up unit 24 that comes into contact with the base material 11 and pushes up the fragments 3 of the semiconductor wafer through the sheet 10 and adheres the fragments 3 to the adhesive surface of the tape 27.

Therefore, the fragments 3 of the semiconductor wafer can be adhered to the tape 27 and removed; therefore, the fragments 3 of the semiconductor wafer are suppressed from adhering to the surfaces of the semiconductor devices 2.

### Embodiment 2

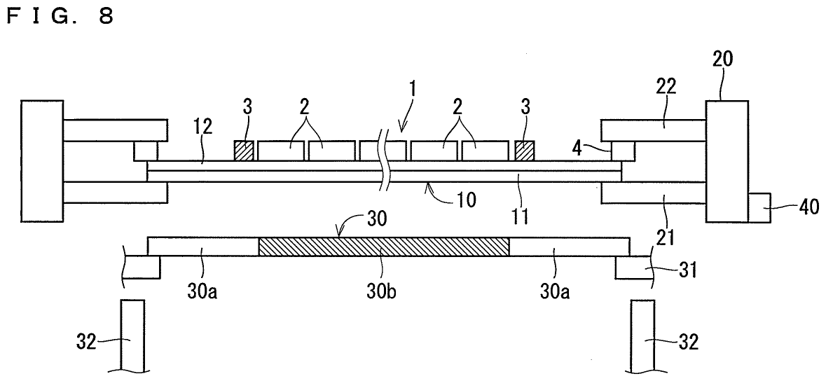

Next, a semiconductor manufacturing apparatus according to Embodiment 2 will be described. FIG. 8 is a side view illustrating a configuration related to reduction in adhesive strength in the semiconductor manufacturing apparatus according to Embodiment 2. Note that in Embodiment 2, the same components as those described in Embodiment 1 are given the same reference numerals, and the description thereof will be omitted.

In Embodiment 1, as illustrated in FIG. 2, one scanning type energy irradiation device 32 is arranged below the base material 11 of the sheet 10. On the other hand, in Embodiment 2, as illustrated in FIG. 8, a plurality of energy irradiation devices 32 are not of the scanning type, and are arranged below the base material 11 of the sheet 10 and on the outer circumferential side thereof. Furthermore, a mask 30 is arranged between the energy irradiation devices 32 and the sheet 10 and is supported by a mask supporter 31. Mask 30 includes an energy transmitting section 30a through which energy irradiated from the energy irradiation devices 32 transmits, and an energy blocking section 30b with which the energy irradiated from the energy irradiation devices 32 is blocked.

The fragments 3 of the semiconductor wafer being formed in the vicinity of the periphery of the semiconductor wafer 1 is known. Therefore, the energy transmitting section 30a is provided at the outer periphery of the mask 30 so that energy is irradiated to the area of the sheet 10 in the vicinity of the periphery of the semiconductor wafer 1 is adhered, and the energy blocking section 30b is provided at the inner peripheral portion of the mask 30 so that energy is not irradiated to an area other than the area.

The mask 30 in FIG. 8 is for performing the process of Step S5 in FIG. 7. When performing the process of Step S7, the mask 30 with the energy transmitting section 30a and the energy blocking section 30b in a reverse positional relationship is used, or energy is irradiated without the mask 30 being arranged.

Here, the energy irradiated from the energy irradiation device 32, that is, the energy for reducing the adhesive strength, is any of light including ultraviolet (UV) light, heating, cooling, or radiation.

Note that the configuration regarding the removal of the fragments 3 of the semiconductor wafer and the method of manufacturing the semiconductor device 2 are the same as in Embodiment 1; therefore, the description thereof is omitted.

As mentioned above, in Embodiment 2, the adhesion strength reducer includes the energy irradiation devices 32 that irradiates energy toward the sheet 10 to reduce the adhesion strength, and the mask 30 arranged between the energy irradiation devices 32 and the sheet 10, and the mask 30 includes the energy blocking section 30b for blocking energy.

Therefore, selective reduction in the adhesion strength of the adhesion layer 12 only in the area on the sheet 10 where the fragments 3 of the semiconductor wafer are adhered is enabled without using a scanning energy irradiation device 32, enabling the removal of only the fragments 3 of the semiconductor wafer before picking up the semiconductor devices. Therefore, scattering of the fragments 3 of the semiconductor wafer and adhering to the surfaces of the semiconductor devices 2 can be suppressed when picking up the semiconductor devices 2 that have been cut into pieces.

It should be noted that Embodiments can be arbitrarily combined and can be appropriately modified or omitted.

Hereinafter, the aspects of the present disclosure will be collectively described as Appendices.

### (Appendix 1)

A semiconductor manufacturing apparatus configured to manufacture a plurality of semiconductor devices obtained by cutting a semiconductor wafer into pieces, comprising:
a sheet holder that holds a sheet having a base material and an adhesive layer provided on a first main surface of the base material to which the semiconductor wafer is adhered; and
an adhesion strength reducer that is arranged to be able to act on the sheet held by the sheet holder and reduces adhesive strength in a predetermined area of the adhesive layer of the sheet, wherein
the predetermined area of the adhesive layer is an area to which fragments of the semiconductor wafer that do not function as the semiconductor devices are adhered.

### (Appendix 2)

The semiconductor manufacturing apparatus according to Appendix 1, wherein
the adhesion strength reducer is an energy irradiation device of scanning type that irradiates the sheet with energy for reducing the adhesion strength while scanning.

### (Appendix 3)

The semiconductor manufacturing apparatus according to Appendix 1, wherein
the adhesion strength reducer includes an energy irradiation device that irradiates energy toward the sheet to reduce adhesive strength, and a mask arranged between the energy irradiation device and the sheet, and
the mask includes an energy blocking section that blocks the energy.

### (Appendix 4)

The semiconductor manufacturing apparatus according to Appendix 2 or 3, wherein
the energy is any of light including ultraviolet light, heating, cooling, or radiation.

### (Appendix 5)

The semiconductor manufacturing apparatus according to any one of Appendices 1 to 4, wherein
the sheet holder is a frame fixing unit that fixes and supports a dicing frame attached to a periphery of the semiconductor wafer.

### (Appendix 6)

The semiconductor manufacturing apparatus according to any one of Appendices 1 to 5, wherein
the sheet holder holds the sheet so that the adhesive layer faces downward, and the semiconductor manufacturing apparatus further comprising
a push-down unit that is brought into contact with the base material and pushes down the fragments of the semiconductor wafer through the sheet.

### (Appendix 7)

The semiconductor manufacturing apparatus according to Appendix 6, further comprising
a rotator that rotates the sheet holder.

### (Appendix 8)

The semiconductor manufacturing apparatus according to any one of Appendices 1 to 5, wherein
the sheet holder holds the sheet so that the base material faces downward, and the semiconductor manufacturing apparatus further comprising:
a push-up unit that is brought into contact with the base material and pushes up the fragments of the semiconductor wafer through the sheet;
a camera that identifies the fragments of the semiconductor wafer;
an air gun that ejects air toward the fragments of the semiconductor wafer; and
a controller that controls the air gun to eject air to remove the fragments of the semiconductor wafer from the adhesive layer when the camera identifies the fragments of the semiconductor wafer peeled off from the adhesive layer by the push-up unit.

### (Appendix 9)

The semiconductor manufacturing apparatus according to any one of Appendices 1 to 5, further comprising
a tape attachment/detachment unit that attaches a tape, having lower adhesive strength than that of the adhesive layer before the adhesive strength thereof is reduced yet and higher adhesive strength than that of adhesive layer after the adhesive strength thereof is reduced, to a surface opposite side of a surface in contact with the adhesive layer in the semiconductor wafer, and then, peels the tape off.

### (Appendix 10)

The semiconductor manufacturing apparatus according to any one of Appendices 1 to 5, further comprising
a tape holder that holds a tape, having lower adhesive strength than that of the adhesive layer before the adhesive strength thereof is reduced yet and higher adhesive strength than that of adhesive layer after the adhesive strength thereof is reduced, above the semiconductor wafer so that the adhesive surface of the tape faces a surface opposite side of a surface in contact with the adhesive layer in the semiconductor wafer; and
a push-up unit that comes into contact with the base material and pushes up the fragments of the semiconductor wafer through the sheet and adheres the fragments to the adhesive surface of the tape.

### (Appendix 11)

A method of manufacturing a semiconductor device, comprising the steps of:
adhering a semiconductor wafer to an adhesive layer of a sheet having a base material and the adhesive layer provided on a first main surface of the base material;
dicing the semiconductor wafer and dividing diced objects into a plurality of semiconductor devices and fragments of the semiconductor wafer that do not function as the semiconductor devices;
reducing adhesion strength in an area of the adhesion layer to which the fragments of the semiconductor wafer are adhered by an adhesion strength reducer;
removing the fragments of the semiconductor wafer from the adhesive layer; and
picking up the plurality of semiconductor devices from the adhesive layer.

### (Appendix 12)

The method of manufacturing the semiconductor device according to Appendix 11, further comprising the step of
reducing adhesion strength of an area of the adhesion layer to which the plurality of semiconductor devices are adhered by the adhesion strength reducer between the step of removing the fragments of the semiconductor wafer from the adhesive layer and the step of picking up the plurality of semiconductor devices from the adhesive layer.

While the invention has been illustrated and described in detail, the foregoing description is in all aspects illustrative and not restrictive. It is therefore understood that numerous modifications and variations can be devised without departing from the scope of the invention.

What is claimed is:

1. A semiconductor manufacturing apparatus configured to manufacture a plurality of semiconductor devices obtained by cutting a semiconductor wafer into pieces, comprising:
a sheet holder that holds a sheet having a base material and an adhesive layer provided on a first main surface of the base material to which the semiconductor wafer is adhered; and
an adhesion strength reducer that is arranged to be able to act on the sheet held by the sheet holder and reduces adhesive strength in a predetermined area of the adhesive layer of the sheet, wherein
the predetermined area of the adhesive layer is an area to which fragments of the semiconductor wafer that do not function as the semiconductor devices are adhered.

2. The semiconductor manufacturing apparatus according to claim 1, wherein
the adhesion strength reducer is an energy irradiation device of scanning type that irradiates the sheet with energy for reducing the adhesion strength while scanning.

3. The semiconductor manufacturing apparatus according to claim 1, wherein
the adhesion strength reducer includes an energy irradiation device that irradiates energy toward the sheet to reduce adhesive strength, and a mask arranged between the energy irradiation device and the sheet, and
the mask includes an energy blocking section that blocks the energy.

4. The semiconductor manufacturing apparatus according to claim 2, wherein
the energy is any of light including ultraviolet light, heating, cooling, or radiation.

5. The semiconductor manufacturing apparatus according to claim 3, wherein
the energy is any of light including ultraviolet light, heating, cooling, or radiation.

6. The semiconductor manufacturing apparatus according to claim 1, wherein
the sheet holder is a frame fixing unit that fixes and supports a dicing frame attached to a periphery of the semiconductor wafer.

7. The semiconductor manufacturing apparatus according to claim 1, wherein
the sheet holder holds the sheet so that the adhesive layer faces downward, and the semiconductor manufacturing apparatus further comprising
a push-down unit that is brought into contact with the base material and pushes down the fragments of the semiconductor wafer through the sheet.

8. The semiconductor manufacturing apparatus according to claim 7, further comprising
a rotator that rotates the sheet holder.

9. The semiconductor manufacturing apparatus according to claim 1, wherein
the sheet holder holds the sheet so that the base material faces downward, and the semiconductor manufacturing apparatus further comprising:
a push-up unit that is brought into contact with the base material and pushes up the fragments of the semiconductor wafer through the sheet;
a camera that identifies the fragments of the semiconductor wafer;
an air gun that ejects air toward the fragments of the semiconductor wafer; and
a controller that controls the air gun to eject air to remove the fragments of the semiconductor wafer from the adhesive layer when the camera identifies the fragments of the semiconductor wafer peeled off from the adhesive layer by the push-up unit.

10. The semiconductor manufacturing device according to claim 1, further comprising
a tape attachment/detachment unit that attaches a tape, having lower adhesive strength than that of the adhesive layer before the adhesive strength thereof is reduced yet and higher adhesive strength than that of adhesive layer after the adhesive strength thereof is reduced, to a surface opposite side of a surface in contact with the adhesive layer in the semiconductor wafer, and then, peels the tape off.

11. The semiconductor manufacturing apparatus according to claim 1, further comprising:
a tape holder that holds a tape, having lower adhesive strength than that of the adhesive layer before the adhesive strength thereof is reduced yet and higher adhesive strength than that of adhesive layer after the adhesive strength thereof is reduced, above the semiconductor wafer so that the adhesive surface of the tape faces a surface opposite side of a surface in contact with the adhesive layer in the semiconductor wafer; and
a push-up unit that comes into contact with the base material and pushes up the fragments of the semiconductor wafer through the sheet and adheres the fragments to the adhesive surface of the tape.

12. A method of manufacturing a semiconductor device, comprising the steps of:
adhering a semiconductor wafer to an adhesive layer of a sheet having a base material and the adhesive layer provided on a first main surface of the base material;
dicing the semiconductor wafer and dividing diced objects into a plurality of semiconductor devices and fragments of the semiconductor wafer that do not function as the semiconductor devices;
reducing adhesion strength in an area of the adhesion layer to which the fragments of the semiconductor wafer are adhered by an adhesion strength reducer;
removing the fragments of the semiconductor wafer from the adhesive layer; and
picking up the plurality of semiconductor devices from the adhesive layer.

13. The method of manufacturing the semiconductor device according to claim 12, further comprising the step of
reducing adhesion strength of an area of the adhesion layer to which the plurality of semiconductor devices are adhered by the adhesion strength reducer between the step of removing the fragments of the semiconductor wafer from the adhesive layer and the step of picking up the plurality of semiconductor devices from the adhesive layer.
